(19) United States
(12) Patent Application Publication
(10) Pub. No.: US 2024/0420935 A1
(43) Pub. Date: Dec. 19, 2024

(54) SUBSTRATE PROCESSING APPARATUS, SUBSTRATE PROCESSING METHOD, AND METHOD FOR MANUFACTURING SEMICONDUCTOR DEVICE

(71) Applicant: Sumitomo Heavy Industries Ion Technology Co., Ltd., Tokyo (JP)

(72) Inventors: Tsunahiko NAITO, Ehime (JP); Hideyuki YAMAUCHI, Ehime (JP)

(21) Appl. No.: 18/820,393

(22) Filed: Aug. 30, 2024

Related U.S. Application Data
(63) Continuation of application No. PCT/JP2023/004751, filed on Feb. 13, 2022.

(30) Foreign Application Priority Data
Mar. 1, 2022 (JP) 2022-031270

(51) Int. Cl. H01J 37/32; H01L 21/265

(52) U.S. Cl. CPC H01J 37/32816; H01J 37/32449; H01J 37/32715; H01J 2237/20214; H01J 2237/24585; H01L 21/265

(57) ABSTRACT

A substrate processing apparatus includes: a vacuum processing chamber; a substrate holder provided in the vacuum processing chamber and holding the substrate; a sealing forming a closed space between the substrate held by the substrate holder and the substrate holder; a gas path communicating with the closed space; a gas supply path supplying a gas into the gas path; a gas exhaust path exhausting the gas from the gas path; a first valve capable of opening and closing a space between the gas path and the gas supply path; and a second valve capable of opening and closing a space between the gas path and the gas exhaust path.

### CROSS-REFERENCE TO RELATED APPLICATIONS

This is a bypass continuation of International PCT Application No. PCT/JP2023/04751, filed on Feb. 13, 2023, which claims priority to Japanese Patent Application No. 2022-031270, filed on Mar. 1, 2022, which are incorporated by reference herein in their entirety.

### BACKGROUND

### Technical Field

Certain embodiments of the present invention relate to a substrate processing apparatus, a substrate processing method, and a method for manufacturing a semiconductor device.

### Description of Related Art

When a substrate is processed in a semiconductor manufacturing process or the like, a heat transfer gas may be supplied between a substrate held by a substrate holder in a vacuum processing chamber and the substrate holder to adjust a temperature of the substrate. For example, the supply of the heat transfer gas is controlled such that a measured pressure value of the heat transfer gas between the substrate and the substrate holder is a setting pressure value (For example, refer to the related art).

### SUMMARY

According to an embodiment of the present disclosure, there is provided a substrate processing apparatus including: a vacuum processing chamber in which processing on a substrate is performed; a substrate holder provided in the vacuum processing chamber and configured to hold the substrate; a sealing configured to form a closed space between the substrate held by the substrate holder and the substrate holder; a hermetic container provided in the vacuum processing chamber and having a gas pressure higher than a gas pressure in the vacuum processing chamber; a gas path provided in the hermetic container and communicating with the closed space; a gas supply path configured to supply a gas into the gas path; a gas exhaust path configured to exhaust the gas from the gas path; a first valve provided in the hermetic container and capable of opening and closing a space between the gas path and the gas supply path; and a second valve provided in the hermetic container and capable of opening and closing a space between the gas path and the gas exhaust path.

According to another embodiment of the present disclosure, there is provided a substrate processing method of processing a substrate held by a substrate holder in a vacuum processing chamber, in which a gas path communicating with a closed space formed between the substrate held by the substrate holder and the substrate holder is connected to a gas supply path via a first valve that is openable and closable, and the gas path is further connected to a gas exhaust path via a second valve that is openable and closable, and the substrate processing method includes: holding the substrate on the substrate holder; closing the first valve to set a gas pressure in the gas supply path to a first target pressure; opening the first valve to supply a gas in the gas supply path to the gas path after the substrate is held by the substrate holder and the gas pressure in the gas supply path becomes the first target pressure; processing a surface of the substrate after the opening of the first valve; closing the first valve and opening the second valve to exhaust the gas in the gas path to the gas exhaust path; and releasing the holding of the substrate performed by the substrate holder after the opening of the second valve.

According to still another embodiment of the present disclosure, there is provided a method for manufacturing a semiconductor device, including: the substrate processing method according to a certain embodiment.

### BRIEF DESCRIPTION OF THE DRAWINGS

FIG. 1 is a top view showing a schematic configuration of a substrate processing apparatus according to an embodiment.

FIG. 2 is a side view showing a schematic configuration of the substrate processing apparatus according to the embodiment.

FIG. 3 is a diagram showing a configuration of a heat transfer gas supply/exhaust system according to the embodiment.

FIG. 4 is a time chart showing an example of an operation of the substrate processing apparatus.

FIG. 5 is a flowchart showing an example of a substrate processing method according to the embodiment.

FIG. 6 is a diagram showing a configuration of a heat transfer gas supply/exhaust system according to a first modification example.

FIG. 7 is a graph showing an example of a pressure change in a gas path when a first valve is opened.

FIG. 8 is a diagram showing a configuration of a heat transfer gas supply/exhaust system according to a second modification example.

### DETAILED DESCRIPTION

In order to improve productivity in a semiconductor manufacturing process, it is preferable that a time required for supplying a heat transfer gas is shorter.

It is desirable to provide a technique for improving productivity in a semiconductor manufacturing process.

Any combination of the above-described components or a replacement of the components and expressions of the present disclosure between methods, devices, systems, and the like is also effective as an aspect of the present disclosure.

Hereinafter, embodiments for implementing a substrate processing apparatus, a substrate processing method, and a method for manufacturing a semiconductor device according to the present disclosure will be described in detail with reference to the drawings. In describing the drawings, the same reference numerals will be assigned to the same elements, and repeated description will be appropriately omitted. In addition, configurations described below are merely examples, and do not limit the scope of the present disclosure in any way.

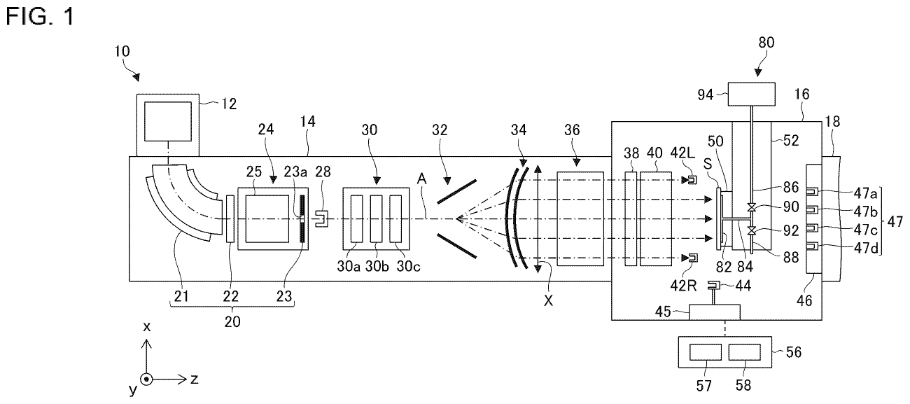

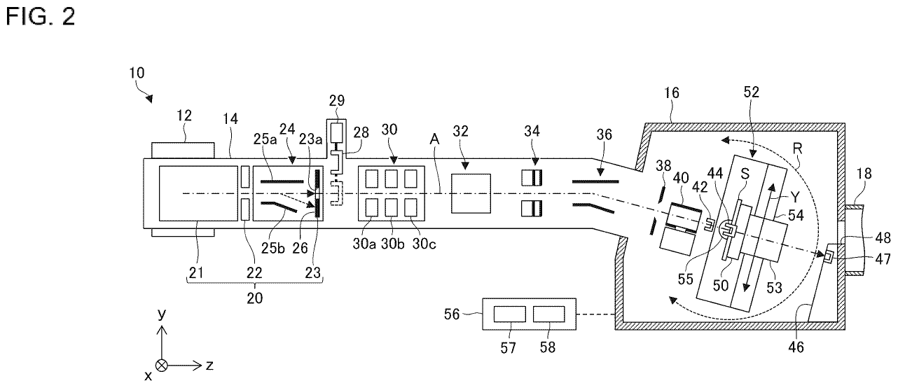

FIG. 1 is a top view showing a schematic configuration of a substrate processing apparatus 10 according to an embodiment. FIG. 2 is a side view showing a schematic configuration of the substrate processing apparatus 10 according to the embodiment. The substrate processing apparatus 10 is an ion implanter configured to perform ion implantation processing on a surface of a workpiece. For example, the workpiece is a substrate, and for example, the workpiece is a semiconductor wafer. For convenience of description, the workpiece may be referred to as a “substrate S” in the description herein. However, this is not intended to limit an implantation processing target to a specific object.

The substrate processing apparatus 10 is configured to irradiate a whole processing surface of the substrate S with a spot-like ion beam by performing a reciprocating scan using the ion beam in one direction and causing the substrate S to reciprocate in a direction perpendicular to a scanning direction. In the description herein, for convenience of description, a traveling direction of the ion beam traveling along a designed beamline A is defined as a z-direction, and a plane perpendicular to the z-direction is defined as an xy-plane. When the substrate S is scanned with the ion beam, the scanning direction of the beam is defined as an x-direction, and a direction perpendicular to the z-direction and the x-direction is defined as a y-direction. Therefore, the reciprocating scan using the beam is performed in the x-direction, and a reciprocating movement of the substrate S is performed in the y-direction.

The substrate processing apparatus 10 includes an ion generation device 12, a beamline unit 14, a vacuum processing chamber 16, and a substrate transfer device 18. The ion generation device 12 is configured to provide an ion beam for the beamline unit 14. The beamline unit 14 is configured to transport the ion beam from the ion generation device 12 to the vacuum processing chamber 16. The substrate S to be subjected to the implantation processing is accommodated in the vacuum processing chamber 16, and the implantation processing of irradiating the substrate S with the ion beam provided from the beamline unit 14 is performed. The substrate transfer device 18 is configured to load an unprocessed substrate before the implantation processing into the vacuum processing chamber 16, and unload a processed substrate after the implantation processing from the vacuum processing chamber 16. The substrate processing apparatus 10 includes a vacuum exhaust system (not shown) for providing a desired vacuum environment for each of the ion generation device 12, the beamline unit 14, the vacuum processing chamber 16, and the substrate transfer device 18.

The beamline unit 14 includes a mass analyzing unit 20, a beam park device 24, a beam shaping unit 30, a beam scan unit 32, a beam parallelizing unit 34, and an angular energy filter (AEF) 36, in an order from an upstream side of the beamline A. The upstream of the beamline A means a side closer to the ion generation device 12, and a downstream of the beamline A means a side closer to the vacuum processing chamber 16 (or a beam stopper 46).

The mass analyzing unit 20 is provided downstream of the ion generation device 12, and is configured to select a required ion species from the ion beam extracted from the ion generation device 12 by performing mass analysis. The mass analyzing unit 20 has a mass analyzing magnet 21, a mass analyzing lens 22, and a mass resolving aperture 23.

The mass analyzing magnet 21 applies a magnetic field to the ion beam extracted from the ion generation device 12, and deflects the ion beam into different paths in accordance with a value of a mass-to-charge ratio M=m/q (m is mass, and q is charge) of the ions. For example, the mass analyzing magnet 21 applies the magnetic field in the y-direction (−y-direction in FIGS. 1 and 2) to the ion beam so that the ion beam is deflected in the x-direction. Magnetic field intensity of the mass analyzing magnet 21 is adjusted such that the ion species having a desired mass-to-charge ratio M passes through the mass resolving aperture 23.

The mass analyzing lens 22 is provided downstream of the mass analyzing magnet 21, and is configured to adjust focusing/defocusing power for the ion beam. The mass analyzing lens 22 adjusts a focusing position of the ion beam passing through the mass resolving aperture 23 in the beam traveling direction (z-direction), and adjusts a mass resolution M/dM of the mass analyzing unit 20. The mass analyzing lens 22 is not an essential configuration, and the mass analyzing unit 20 may not have the mass analyzing lens 22.

The mass resolving aperture 23 is provided downstream of the mass analyzing lens 22, and is provided at a position away from the mass analyzing lens 22. The mass resolving aperture 23 is configured such that a beam deflection direction (x-direction) of the mass analyzing magnet 21 coincides with a slit width direction, and has an opening 23a having a shape which is relatively short in the x-direction and relatively long in the y-direction.

The mass resolving aperture 23 may be configured such that the slit width is variable for adjusting the mass resolution. The mass resolving aperture 23 may be configured to include two beam shield members that are movable in a slit width direction, and may be configured such that the slit width is adjustable by changing an interval between the two beam shield members. The mass resolving aperture 23 may be configured such that the slit width is variable by switching to any one of a plurality of slits having different slit widths.

The beam park device 24 is configured to cause the ion beam to temporarily retreat from the beamline A and to block the ion beam directed to the vacuum processing chamber 16 (or the substrate S) located downstream. The beam park device 24 can be disposed at any position in an intermediate portion of the beamline A. For example, the beam park device 24 can be disposed between the mass analyzing lens 22 and the mass resolving aperture 23. A prescribed distance is required between the mass analyzing lens 22 and the mass resolving aperture 23. Accordingly, the beam park device 24 is disposed between both of these. In this manner, a length of the beamline A can be shortened, compared to a case where the beam park device 24 is disposed at another position. Therefore, the whole substrate processing apparatus 10 can be reduced in size.

The beam park device 24 includes a pair of park electrodes 25 (25a and 25b) and a beam dump 26. The pair of park electrodes 25a and 25b faces each other across the beamline A, and faces in a direction (y-direction) perpendicular to the beam deflection direction (x-direction) of the mass analyzing magnet 21. The beam dump 26 is provided on the downstream side of the beamline A from the park electrodes 25a and 25b, and is provided away from the beamline A in a facing direction of the park electrodes 25a and 25b.

The first park electrode 25a is disposed on an upper side of the beamline A in a direction of gravity, and the second park electrode 25b is disposed on a lower side of the beamline A in the direction of gravity. The beam dump 26 is provided at a position away to the lower side of the beamline A in the direction of gravity, and is disposed on the lower side of the opening 23a of the mass resolving aperture 23 in the direction of gravity. For example, the beam dump 26 is configured to include a portion of the mass resolving aperture 23 where the opening 23a is not formed. The beam dump 26 may be configured to be separate from the mass resolving aperture 23.

The beam park device 24 deflects the ion beam by using an electric field applied between the pair of park electrodes 25a and 25b, and causes the ion beam to retreat from the beamline A. For example, a negative voltage is applied to the second park electrode 25b, with reference to a potential of the first park electrode 25a. In this manner, the ion beam is deflected downward from the beamline A in the direction of gravity, and is incident into the beam dump 26. In FIG. 2, a trajectory of the ion beam directed toward the beam dump 26 is indicated by a broken line. The beam park device 24 causes the ion beam to pass toward the downstream side along the beamline A by setting the pair of park electrodes 25a and 25b to have the same potential. The beam park device 24 is configured to be operable by switching between a first mode in which the ion beam passes toward the downstream side and a second mode in which the ion beam is incident into the beam dump 26.

An injector Faraday cup 28 is provided downstream of the mass resolving aperture 23. The injector Faraday cup 28 is configured to be movable into and out of the beamline A by an operation of an injector drive unit 29. The injector drive unit 29 moves the injector Faraday cup 28 in a direction (for example, the y-direction) perpendicular to an extending direction of the beamline A. When the injector Faraday cup 28 is disposed on the beamline A as shown by a broken line in FIG. 2, the injector Faraday cup 28 blocks the ion beam directed toward the downstream side. On the other hand, as shown by a solid line in FIG. 2, when the injector Faraday cup 28 is removed from the beamline A, the blocking of the ion beam directed toward the downstream side is released.

The injector Faraday cup 28 is configured to measure a beam current of the ion beam subjected to mass analysis performed by the mass analyzing unit 20. The injector Faraday cup 28 can measure a mass analysis spectrum of the ion beam by measuring the beam current while changing the magnetic field intensity of the mass analyzing magnet 21. The mass resolution of the mass analyzing unit 20 can be calculated using the measured mass analysis spectrum.

The beam shaping unit 30 includes a focusing/defocusing device such as a focusing/defocusing quadrupole lens (Q-lens), and is configured to shape the ion beam, which has passed through the mass analyzing unit 20, such that the ion beam has a desired cross-sectional shape. For example, the beam shaping unit 30 is configured to include an electric field type three-stage quadrupole lens (also referred to as a triplet Q-lens), and has three quadrupole lenses 30a, 30b, and 30c. The beam shaping unit 30 adopts the three lens devices 30a to 30c. Accordingly, the beam shaping unit 30 can independently adjust the ion beam to focus or defocus in each of the x-direction and the y-direction. The beam shaping unit 30 may include a magnetic field type lens device, or may include a lens device that shapes the beam by using both an electric field and a magnetic field.

The beam scan unit 32 is a beam deflection device configured to provide reciprocating scan using the beam and to perform scanning using the shaped ion beam in the x-direction. The beam scan unit 32 has a pair of scanning electrodes facing each other in the beam scanning direction (x-direction). The pair of scanning electrodes is connected to a variable voltage power supply (not shown), which periodically changes a voltage applied between the pair of scanning electrodes. In this manner, an electric field generated between the electrodes is changed so that the ion beam is deflected at various angles. As a result, a whole scanning range is scanned with the ion beam in the x-direction. In FIG. 1, the scanning direction and the scanning range of the beam are indicated by an arrow X, and a plurality of trajectories of the ion beam in the scanning range are indicated by one dot chain line. The beam scan unit 32 may be replaced with another beam scan unit, and the beam scan unit may be configured to serve as a magnet device using a magnetic field.

The beam parallelizing unit 34 is configured such that the traveling direction of the ion beam used for the scanning is parallel to the trajectory of the designed beamline A. The beam parallelizing unit 34 has a plurality of arc-shaped parallelizing lens electrodes in each of which an ion beam passing slit is provided in a central portion in the y-direction. The parallelizing lens electrode is connected to a high-voltage power supply (not shown), and applies an electric field generated by voltage application to the ion beam so that the traveling directions of the ion beams are parallelized. The beam parallelizing unit 34 may be replaced with another beam parallelizing device, and the beam parallelizing device may be configured to serve as a magnet device using a magnetic field.

An acceleration/deceleration (AD) column (not shown) for accelerating or decelerating the ion beam may be provided downstream of the beam parallelizing unit 34.

The angular energy filter (AEF) 36 is configured to analyze energy of the ion beam, to deflect ions having necessary energy downward, and to guide the ions to the vacuum processing chamber 16. The angular energy filter 36 has a pair of AEF electrodes for electric field deflection. The pair of AEF electrodes is connected to a high-voltage power supply (not shown). In FIG. 2, the ion beam is deflected downward by applying a positive voltage to the upper AEF electrode and applying a negative voltage to the lower AEF electrode. The angular energy filter 36 may be configured to include a magnetic device for deflection by a magnetic field, or may be configured to include a combination of the pair of AEF electrodes for electric field deflection and the magnet device.

In this way, the beamline unit 14 supplies the ion beam to be used for irradiating the substrate S to the vacuum processing chamber 16. In the present embodiment, the ion generation device 12 and the beamline unit 14 are also referred to as a beam generation device. The beam generation device is configured to generate the ion beam for achieving desired processing conditions by adjusting operation parameters of various devices forming the beam generation device.

The vacuum processing chamber 16 includes an energy defining slit 38, a plasma shower device 40, a side cup 42 (42L and 42R), a profiler cup 44, and a beam stopper 46, in an order from the upstream side of the beamline A. The vacuum processing chamber 16 includes a substrate holder 50 that holds one or a plurality of substrates S, and a support mechanism 52 that supports the substrate holder 50.

The energy defining slit 38 is provided on the downstream side of the angular energy filter 36, and analyzes the energy of the ion beam incident into the substrate S together with the angular energy filter 36. The energy defining slit 38 is an energy defining slit (EDS) configured to include a slit that is horizontally long in the beam scanning direction (x-direction). The energy defining slit 38 causes the ion beam having a desired energy value or a desired energy range to pass toward the substrate S, and blocks other ion beams.

The plasma shower device 40 is located on the downstream side of the energy defining slit 38. The plasma shower device 40 supplies a low-energy electron to the ion beam and a surface of the substrate S (substrate processing surface) in accordance with a beam current amount of the ion beam, and suppresses charge-up caused by positive charges accumulated by ion implantation on the substrate processing surface. For example, the plasma shower device 40 includes a shower tube through which the ion beam passes, and a plasma generating device that supplies electrons into the shower tube.

The side cup 42 (42L and 42R) is configured to measure the beam current of the ion beam during the ion implantation processing into the substrate S. The side cups 42L and 42R are disposed to be shifted to the left and right (x-direction) with respect to the substrate S disposed on the beamline A, and are disposed at positions in which the ion beam directed toward the substrate S is not blocked during the ion implantation. The ion beam is used for scanning in the x-direction beyond a range where the substrate S is located. Accordingly, a portion of the beam used for the scanning is incident into the side cups 42L and 42R even during the ion implantation. In this manner, the beam current amount during the ion implantation processing is measured by the side cups 42L and 42R.

The profiler cup 44 is a Faraday cup configured to measure the beam current on the substrate processing surface. The profiler cup 44 is configured to be movable by an operation of a profiler driving device 45, retreats from an implantation position where the substrate S is located during the ion implantation, and is inserted into the implantation position when the substrate S is not located at the implantation position. The profiler cup 44 measures the beam current while moving in the x-direction. In this manner, the profiler cup 44 can measure the beam current over the whole beam scanning range in the x-direction. In the profiler cup 44, a plurality of Faraday cups may be aligned in the x-direction to be formed in an array shape so that the beam currents can be simultaneously measured at a plurality of positions in the beam scanning direction (x-direction).

At least one of the side cup 42 and the profiler cup 44 may include a single Faraday cup for measuring the beam current amount, or may include an angle measurement device for measuring angle information of the beam. For example, the angle measurement device includes a slit and a plurality of current detectors provided away from the slit in the beam traveling direction (z-direction). For example, the angle measurement device can measure an angle component of the beam in the slit width direction by causing the plurality of current detectors aligned in the slit width direction to measure the beams passing through the slit. At least one of the side cup 42 and the profiler cup 44 may include a first angle measurement device capable of measuring angle information in the x-direction and a second angle measurement device capable of measuring angle information in the y-direction.

The substrate holder 50 includes an electrostatic chuck for holding the substrate S. The substrate holder 50 is supported by the support mechanism 52. The support mechanism 52 includes a twist mechanism 53, a reciprocating movement mechanism 54, and a tilt mechanism 55.

The twist mechanism 53 is a mechanism for adjusting a rotation angle of the substrate S. The twist mechanism 53 rotates the substrate S around a normal line of the substrate processing surface as a rotation center axis. In this manner, the twist mechanism 53 adjusts a twist angle between an alignment mark provided in an outer peripheral portion of the substrate S and a reference position. Here, the alignment mark of the substrate S means a notch or an orientation flat provided in the outer peripheral portion of the substrate S, and means a mark that serves as a reference for a crystal axis direction of the substrate S or an angular position of the substrate S in a circumferential direction. The twist mechanism 53 is provided between the substrate holder 50 and the reciprocating movement mechanism 54.

The reciprocating movement mechanism 54 causes the twist mechanism 53 to reciprocate in a reciprocating movement direction (y-direction) perpendicular to the beam scanning direction (x-direction). In this manner, the substrate S held by the substrate holder 50 is caused to reciprocate in the y-direction. In FIG. 2, the reciprocating movement of the substrate S is indicated by an arrow Y as an example.

The tilt mechanism 55 adjusts tilting of the substrate S, and adjusts a tilt angle between the traveling direction of the ion beam directed toward the substrate processing surface and the normal line of the substrate processing surface. In the present embodiment, among tilt angles of the substrate S, an angle at which the axis in the x-direction is a rotation center axis is adjusted as the tilt angle. The tilt mechanism 55 is provided between the reciprocating movement mechanism 54 and an inner wall of the vacuum processing chamber 16, and is configured to adjust the tilt angle of the substrate S held by the substrate holder 50 by rotating the reciprocating movement mechanism 54 in an R-direction.

The support mechanism 52 is configured such that the substrate S held by the substrate holder 50 is movable between an implantation position where the substrate S is irradiated with the ion beam and a transfer position where the substrate S is loaded from or unloaded to the substrate transfer device 18. FIG. 2 shows a state where the substrate S is located at the implantation position, and the support mechanism 52 supports the substrate holder 50 such that the substrate S held by the substrate holder 50 and the beamline A are in a position and a direction in which both of these intersect with each other. The transfer position of the substrate S corresponds to a position of the substrate holder 50 when the substrate S is loaded or unloaded through a transfer port 48 by a transfer mechanism or a transfer robot provided in the substrate transfer device 18.

The beam stopper 46 is provided on the most downstream side of the beamline A, and is attached to the inner wall of the vacuum processing chamber 16, for example. When the substrate S does not exist on the beamline A, the ion beam is incident into the beam stopper 46. The beam stopper 46 is located close to the transfer port 48 that connects the vacuum processing chamber 16 and the substrate transfer device 18 to each other, and is provided at a position vertically below the transfer port 48.

The beam stopper 46 has a plurality of tuning cups 47 (47a, 47b, 47c, and 47d). The plurality of tuning cups 47 are Faraday cups configured to measure the beam current of the ion beam incident into the beam stopper 46. The plurality of tuning cups 47 are disposed at an interval in the x-direction. For example, the plurality of tuning cups 47 are used for easily measuring the beam currents at the implantation position without using the profiler cup 44.

The side cup 42 (42L, 42R), the profiler cup 44, and the tuning cup 47 (47a to 47d) are beam measurement devices for measuring the beam current as a physical quantity of the ion beam, or beam detectors for detecting the beam current. The side cup 42 (42L, 42R), the profiler cup 44, and the tuning cup 47 (47a to 47d) are beam measurement devices for measuring a beam angle as a physical quantity of the ion beam, or beam detectors for detecting the beam angle.

The substrate processing apparatus 10 further includes a control device 56. The control device 56 controls an overall operation of the substrate processing apparatus 10. The control device 56 is achieved in hardware by elements such as a CPU and a memory of a computer or a mechanical device, and is achieved in software by a computer program. Various functions provided by the control device 56 can be achieved by cooperation between the hardware and the software.

The control device 56 includes a processor 57 such as a central processing unit (CPU), a memory 58 such as a random-access memory (RAM), a read-only memory (ROM), or the like. For example, the control device 56 controls an overall operation of the substrate processing apparatus 10 in accordance with the program by causing the processor 57 to execute the program stored in the memory 58. The processor 57 may execute a program stored in any storage device different from the memory 58, may execute a program acquired from any storage medium by a reading device, or may execute a program acquired via a network. The memory 58 storing the program may be a volatile memory such as a dynamic random-access memory (DRAM), or may be a non-volatile memory such as an electrically erasable programmable read-only memory (EEPROM), a flash memory, a magnetic resistance memory, a resistance change type memory, or a ferroelectric memory. A non-volatile memory, magnetic storage mediums such as a magnetic tape and a magnetic disk, and an optical storage medium such as an optical disk are examples of a non-transitory and tangible computer readable storage medium.

Various functions provided by the control device 56 may be achieved by a single device including the processor 57 and the memory 58, or may be achieved by the cooperation of a plurality of devices, each of which includes the processor 57 and the memory 58.

The substrate processing apparatus 10 further includes a heat transfer gas supply/exhaust system 80. The heat transfer gas supply/exhaust system 80 is configured to supply a gas to a closed heat transfer space 82 between the substrate S held by the substrate holder 50 and the substrate holder 50 and to exhaust the gas from the heat transfer space 82. The gas supplied to the heat transfer space 82 is used to adjust a temperature of the substrate S. The heat transfer gas supply/exhaust system 80 includes a gas path 84 that communicates with the heat transfer space 82, a gas supply path 86 through which the gas is supplied to the gas path 84, a gas exhaust path 88 through which the gas is exhausted from the gas path 84, a first valve 90 that is capable of opening and closing a space between the gas path 84 and the gas supply path 86, a second valve 92 that is capable of opening and closing a space between the gas path 84 and the gas exhaust path 88, and a gas supply source 94 that supplies the gas to the gas supply path 86.

The heat transfer gas supply/exhaust system 80 controls the supply of the gas to the gas path 84 and the exhaust of the gas from the gas path 84 by controlling the opening and closing of the first valve 90 and the second valve 92. The heat transfer gas supply/exhaust system 80 supplies the gas to the heat transfer space 82 from the gas supply path 86 through the gas path 84 by opening the first valve 90 and closing the second valve 92. The heat transfer gas supply/exhaust system 80 exhausts the gas from the heat transfer space 82 to the gas exhaust path 88 through the gas path 84 by closing the first valve 90 and opening the second valve 92.

The heat transfer gas supply/exhaust system 80 supplies the gas to the heat transfer space 82 by closing the second valve 92 and opening the first valve 90 in a state where an unprocessed substrate is held by the substrate holder 50. In a case where the holding of the processed substrate performed by the substrate holder 50 is released, the heat transfer gas supply/exhaust system 80 exhausts the gas from the heat transfer space 82 by closing the first valve 90 and opening the second valve 92 before the release of the holding of the substrate S.

The heat transfer gas supply/exhaust system 80 closes the first valve 90 and fills the gas supply path 86 with a gas having an overfilling pressure (also referred to as a first target pressure P1) from the gas supply source 94. The heat transfer gas supply/exhaust system 80 opens the first valve 90 after filling with the gas having the overfilling pressure, and thus shortens a time until a gas pressure in the heat transfer space 82 becomes a preferable pressure (also referred to as a second target pressure P2) for the temperature adjustment of the substrate S. According to the present disclosure, the gas supply to the heat transfer space 82 can be accelerated, and productivity of the substrate processing apparatus 10 can be improved. The heat transfer gas supply/exhaust system 80 closes the first valve 90 in a case where the gas is exhausted from the heat transfer space 82, so that the gas supply path 86 can be overfilled with the gas at the same time as the gas is exhausted from the heat transfer space 82. As a result, an additional processing time for overfilling with the gas can be reduced, and the productivity of the substrate processing apparatus 10 can be improved.

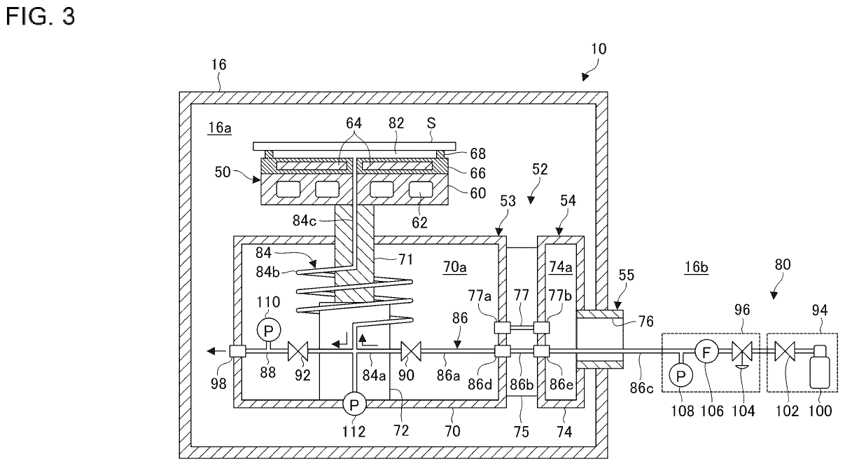

FIG. 3 is a diagram showing a configuration of the heat transfer gas supply/exhaust system 80 according to the embodiment. FIG. 3 shows details of the substrate holder 50 and the support mechanism 52 to which a part of the heat transfer gas supply/exhaust system 80 is provided. Before describing details of the heat transfer gas supply/exhaust system 80, configurations of the substrate holder 50 and the support mechanism 52 will be described.

The substrate holder 50 includes a stage 60, a fluid flow path 62, a chuck electrode 64, an insulation layer 66, and a sealing 68.

The stage 60 is a base portion of the substrate holder 50, and is made of a metal material such as aluminum or stainless steel. The stage 60 is attached to one end of a support shaft 71, and is supported by the support mechanism 52 via the support shaft 71. The fluid flow path 62 is provided inside the stage 60. The fluid flow path 62 is a flow path through which a temperature-adjusting fluid such as water for adjusting a temperature of the stage 60 flows. The temperature of the stage 60 can be adjusted by changing the temperature of the temperature-adjusting fluid supplied to the fluid flow path 62.

The chuck electrode 64 is provided inside the insulation layer 66. The chuck electrode 64 generates an attraction force for the substrate S based on electrostatic attraction with a DC voltage applied by a power source (not shown). The insulation layer 66 is provided on an upper surface of the stage 60. The insulation layer 66 is formed of, for example, a resin material such as polyimide, or a ceramic material such as aluminum nitride (AlN) or aluminum oxide (Al₂O₃). The sealing 68 that is in direct contact with the substrate S is provided in an outer peripheral portion of the insulation layer 66. The substrate S is supported by the sealing 68. The heat transfer space 82 formed between the substrate S and the insulation layer 66 is hermetically closed by the sealing 68. A plurality of protrusions for supporting the substrate S may be formed on a surface of the insulation layer 66 facing the substrate S.

The twist mechanism 53 has a first hermetic container 70, the support shaft 71, and a motor 72. The first hermetic container 70 is a casing that accommodates various devices configuring the twist mechanism 53, and is provided inside the vacuum processing chamber 16. The support shaft 71 extends from the first hermetic container 70 toward the substrate holder 50, and supports the substrate holder 50. The support shaft 71 is configured to be rotatable around an axis with respect to the first hermetic container 70. The motor 72 is provided inside the first hermetic container 70 and is configured to rotate the support shaft 71. By driving the motor 72, the support shaft 71 is rotated, and a twist angle of the substrate holder 50 attached to one end of the support shaft 71 is variably controlled.

The reciprocating movement mechanism 54 has a second hermetic container 74 and a linear actuator 75. The second hermetic container 74 is a casing that accommodates various devices configuring the reciprocating movement mechanism 54, and is provided inside the vacuum processing chamber 16. The second hermetic container 74 is attached to the tilt mechanism 55, and is configured to be rotated with respect to the vacuum processing chamber 16 by the tilt mechanism 55. The linear actuator 75 is provided between the first hermetic container 70 and the second hermetic container 74, and is configured to cause the first hermetic container 70 to reciprocate with respect to the second hermetic container 74.

The tilt mechanism 55 has a communication port 76. The communication port 76 is provided to penetrate a wall of the vacuum processing chamber 16, and is configured to cause an internal space 74a of the second hermetic container 74 to communicate with an external space 16b of the vacuum processing chamber 16. With the communication port 76, a gas pressure in the internal space 74a of the second hermetic container 74 becomes the same as a gas pressure in the external space 16b of the vacuum processing chamber 16, and becomes, for example, the atmospheric pressure (760 torr).

The support mechanism 52 further includes a communication path 77. The communication path 77 is configured to connect an internal space 70a of the first hermetic container 70 and the internal space 74a of the second hermetic container 74 to each other. The communication path 77 connects a first connection port 77a provided in a wall of the first hermetic container 70 and a second connection port 77b provided in a wall of the second hermetic container 74 to each other. With the communication path 77, the gas pressure in the internal space 70a of the first hermetic container 70 becomes the same as the gas pressure in the internal space 74a of the second hermetic container 74, and becomes, for example, the atmospheric pressure (760 torr). The first hermetic container 70 and the second hermetic container 74 may be referred to as atmospheric boxes provided inside the vacuum processing chamber 16. The gas pressures in the internal space 70a of the first hermetic container 70 and the internal space 74a of the second hermetic container 74 need not be the atmospheric pressure, and may be any gas pressure (for example, 100 torr or higher) higher than the gas pressure in the internal space 16a of the vacuum processing chamber 16.

The heat transfer gas supply/exhaust system 80 includes the heat transfer space 82, the gas path 84, the gas supply path 86, the gas exhaust path 88, the first valve 90, the second valve 92, the gas supply source 94, a mass flow controller 96, and a gas exhaust port 98.

The heat transfer space 82 is a space closed by the substrate S held by the substrate holder 50, the insulation layer 66, and the sealing 68. The gas supplied to the heat transfer space 82 promotes heat transfer between the substrate S and the substrate holder 50. For example, in a case where the substrate holder 50 is cooled by water flowing through the fluid flow path 62, the gas in the heat transfer space 82 promotes heat transfer from the substrate S to the substrate holder 50 to cool the substrate S. The gas pressure in the heat transfer space 82 is set to 1 torr or higher and 100 torr or lower in order to promote heat transfer, and is, for example, 3 torr or higher and 30 torr or lower, and is preferably 5 torr or higher and 15 torr or lower.

The gas path 84 has a first gas path 84a, a second gas path 84b, and a third gas path 84c. The first gas path 84a is provided in the internal space 70a of the first hermetic container 70 and extends between the first valve 90 and the second valve 92. The second gas path 84b is provided in the internal space 70a of the first hermetic container 70 and extends spirally around the support shaft 71. The third gas path 84c extends inside the substrate holder 50 and the support shaft 71. The second gas path 84b is spirally formed, thereby reconciling both the rotation of the third gas path 84c with respect to the first gas path 84a and the connection between the first gas path 84a and the third gas path 84c. The second gas path 84b may be rotatably connected between the first gas path 84a and the third gas path 84c by having a mechanical sealing mechanism without rotation restriction instead of being spirally formed.

The gas supply path 86 is provided between the first valve 90 and the mass flow controller 96. The gas supply path 86 has a first gas supply path 86a, a second gas supply path 86b, a third gas supply path 86c, a first connecting part 86d, and a second connecting part 86e. The first gas supply path 86a is provided in the internal space 70a of the first hermetic container 70 and extends between the first valve 90 and the first connecting part 86d. The second gas supply path 86b is provided in the internal space 16a of the vacuum processing chamber 16 and extends between the first hermetic container 70 and the second hermetic container 74. The third gas supply path 86c is provided in the internal space 74a of the second hermetic container 74 and the external space 16b of the vacuum processing chamber 16. The first connecting part 86d is provided on the wall of the first hermetic container 70 and connects the first gas supply path 86a and the second gas supply path 86b to each other. The second connecting part 86e is provided on the wall of the second hermetic container 74 and connects the second gas supply path 86b and the third gas supply path 86c to each other.

The gas exhaust path 88 is provided in the internal space 70a of the first hermetic container 70, and connects the second valve 92 and the gas exhaust port 98 to each other. The gas exhaust port 98 is provided in the wall of the first hermetic container 70 and exhausts the gas toward the internal space 16a of the vacuum processing chamber 16. The gas exhausted into the internal space 16a of the vacuum processing chamber 16 through the gas exhaust port 98 is exhausted to an outside of the vacuum processing chamber 16 through a vacuum exhaust system (not shown) of the vacuum processing chamber 16. In addition, by providing an additional gas exhaust path that connects the gas exhaust port 98 and the vacuum exhaust system to each other, the gas that passes through the gas exhaust path 88 may be exhausted to the outside of the vacuum processing chamber 16 without passing through the internal space 16a of the vacuum processing chamber 16.

The first valve 90 and the second valve 92 are provided in the internal space 70a of the first hermetic container 70. The first valve 90 and the second valve 92 are, for example, solenoid valves, and are configured to be openable and closable in accordance with a command from the control device 56.

The gas supply source 94 is provided outside the vacuum processing chamber 16. The gas supply source 94 supplies a gas to the mass flow controller 96. The gas supply source 94 supplies a gas having a gas pressure higher than the overfilling pressure (first target pressure P1). The gas supply source 94 has a gas cylinder 100 that accommodates the gas and a valve 102 that is capable of opening and closing a space between the gas cylinder 100 and the mass flow controller 96. The valve 102 may be a solenoid valve that is openable and closable in accordance with a command from the control device 56, or may be a gate valve that is manually openable and closable.

The mass flow controller 96 is provided outside the vacuum processing chamber 16. The mass flow controller 96 has a flow rate control valve 104, a flow rate sensor 106, and a first pressure sensor 108. The flow rate control valve 104 is configured to variably control a flow rate of the gas supplied from the gas supply source 94 to the gas supply path 86. The flow rate sensor 106 measures the flow rate of the gas flowing through the gas supply path 86. The first pressure sensor 108 measures a gas pressure in the gas supply path 86. The control device 56 acquires measurement values of the flow rate sensor 106 and the first pressure sensor 108.

The mass flow controller 96 variably controls the flow rate of the gas supplied to the gas supply path 86 by controlling an opening degree of the flow rate control valve 104, in accordance with a command from the control device 56. The mass flow controller 96 may variably control the gas flow rate, based on measurement results of the flow rate sensor 106 and the first pressure sensor 108. For example, based on a target pressure instructed from the control device 56, the mass flow controller 96 may variably control the gas flow rate such that the gas pressure in the gas supply path 86 becomes the target pressure.

The heat transfer gas supply/exhaust system 80 may further include a second pressure sensor 110 and a third pressure sensor 112. The second pressure sensor 110 is provided in the internal space 70a of the first hermetic container 70, and measures the gas pressure in the gas exhaust path 88. The third pressure sensor 112 is provided in the internal space 70a of the first hermetic container 70, and measures the gas pressure in the gas path 84. The control device 56 may acquire a measurement value of at least one of the second pressure sensor 110 and the third pressure sensor 112.

The third pressure sensor 112 may have a differential pressure sensor, and may output a differential pressure signal indicating whether or not a difference between the gas pressure in the internal space 16a of the vacuum processing chamber 16 and the gas pressure in the gas path 84 exceeds a predetermined threshold. Here, the predetermined threshold can be a lower limit value of a preferable gas pressure for heat transfer in the heat transfer space 82, and can be set in a range of, for example, 1 torr or more and 5 torr or less. The control device 56 may acquire the differential pressure signal from the differential pressure sensor.

The third pressure sensor 112 may have a plurality of differential pressure sensors. The third pressure sensor 112 may have a first differential pressure sensor and a second differential pressure sensor. The first differential pressure sensor may output a first differential pressure signal indicating whether or not the difference between the gas pressure in the internal space 16a of the vacuum processing chamber 16 and the gas pressure in the gas path 84 exceeds a first threshold. The second differential pressure sensor may output a second differential pressure signal indicating whether or not the difference between the gas pressure in the internal space 16a of the vacuum processing chamber 16 and the gas pressure in the gas path 84 exceeds a second threshold higher than the first threshold. Here, the first threshold can be the lower limit value of the preferable gas pressure for the heat transfer in the heat transfer space 82, and can be set in a range of, for example, 1 torr or more and 5 torr or less. The second threshold can be an upper limit value of the preferable gas pressure for the heat transfer in the heat transfer space 82, and can be set in a range of, for example, 15 torr or more and 100 torr or less. The second threshold may be set in a range of, for example, 30 torr or higher and 70 torr or lower. The control device 56 may acquire the first differential pressure signal and the second differential pressure signal.

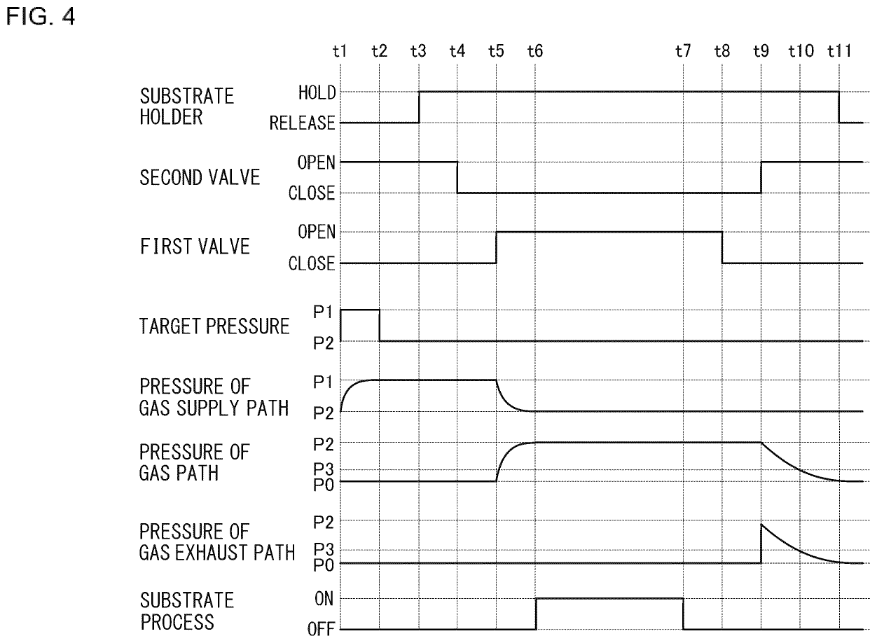

FIG. 4 is a time chart showing an example of the operation of the substrate processing apparatus 10. FIG. 4 shows a flow in which an unprocessed substrate is loaded into the vacuum processing chamber 16, processing is performed on the surface of the substrate S, and a processed substrate is unloaded from the vacuum processing chamber 16.

A first timing t1 in FIG. 4 is a state before the unprocessed substrate is disposed in the substrate holder 50. At the first timing t1, the substrate S is not held by the substrate holder 50, the second valve 92 is opened, and the first valve 90 is closed. At the first timing t1, the filling of the gas supply path 86 with the gas to be having an overfilling pressure (first target pressure P1) is started. The control device 56 sets a target pressure of the mass flow controller 96 to the first target pressure P1. The mass flow controller 96 opens the flow rate control valve 104 to start the supply of the gas to the gas supply path 86, and increases the gas pressure in the gas supply path 86 to the first target pressure P1. For example, the gas pressure in the gas supply path 86 reaches the first target pressure P1 at a second timing t2 after a predetermined time elapses from the first timing t1. A required time from the first timing t1 to the second timing t2 is, for example, 0.5 second or longer and 5 seconds or shorter, and is preferably 2 seconds or shorter. The control device 56 sets a target pressure of the mass flow controller 96 to the second target pressure P2 after the gas pressure in the gas supply path 86 becomes the first target pressure P1 or higher.

The first target pressure P1 is higher than the second target pressure P2 which is preferable for the temperature adjustment of the substrate S. The second target pressure P2 is 1 torr or higher and 100 torr or lower, is, for example, 3 torr or higher and 30 torr or lower, and is preferably 5 torr or higher and 15 torr or lower. The first target pressure P1 is 2 torr or higher and 2100 torr or lower, is, for example, 6 torr or higher and 630 torr or lower, and is preferably 10 torr or higher and 315 torr or lower. At the first timing t1, the gas pressure of the gas supply path 86 is the second target pressure P2. At the first timing t1, the gas pressures in the gas path 84 and the gas exhaust path 88 are equivalent to a gas pressure (also referred to as a high vacuum pressure P0) in the internal space 16a of the vacuum processing chamber 16 which is in a high vacuum state required for the implantation processing. The high vacuum pressure P0 is less than 1 torr and is, for example, 10⁻³ torr or less, or 10⁻⁵ torr or less.

The mass flow controller 96 may control the gas pressure in the gas supply path 86 such that the gas pressure becomes the first target pressure P1, by controlling the flow rate of the gas supplied to the gas supply path 86 and a supply time of the gas with the flow rate control valve 104, based on the measurement value of the flow rate sensor 106. The mass flow controller 96 may control the gas pressure in the gas supply path 86 such that the gas pressure becomes the first target pressure P1, by controlling the flow rate of the gas supplied to the gas supply path 86 with the flow rate control valve 104, based on the measurement value of the first pressure sensor 108.

At a third timing t3 in FIG. 4, the unprocessed substrate is disposed on the substrate holder 50, and the holding of the substrate S performed by the substrate holder 50 is started. For example, a voltage is applied to the chuck electrode 64 of the substrate holder 50, so that the substrate S is held by electrostatic attraction. At the third timing t3 at which the unprocessed substrate is disposed in the substrate holder 50, the second valve 92 is opened, and the first valve 90 is closed. The third timing t3 at which the unprocessed substrate is held by the substrate holder 50 may be before the second timing t2 at which the gas pressure in the gas supply path 86 becomes the first target pressure P1, or may be before the first timing t1 at which the overfilling of the gas supply path 86 with the gas starts.

Subsequently, the second valve 92 is closed at a fourth timing t4, and the first valve 90 is opened at a fifth timing t5 thereafter. The opening of the first valve 90 is executed under a condition that the substrate S is held by the substrate holder 50 and the pressure in the gas supply path 86 is the first target pressure P1. It is preferable that the closing of the second valve 92 is also the condition for the opening of the first valve 90. However, in implementation on a device, a sequential relationship between the fourth timing t4 at which the second valve 92 is closed and the fifth timing t5 at which the first valve 90 is opened is not strictly required. That is, the fifth timing t5 at which the first valve 90 is opened may be simultaneous with the fourth timing t4 at which the second valve 92 is closed, or may be slightly earlier than the fourth timing t4 at which the second valve 92 is closed.

When the first valve 90 is opened at the fifth timing t5, the gas is supplied from the gas supply path 86 to the gas path 84. As a result, the pressure in the gas supply path 86 decreases from the first target pressure P1, and the pressure in the gas path 84 increases from the high vacuum pressure P0. At a subsequent sixth timing t6, an equilibrium state in which the pressure in the gas path 84 and the pressure in the gas supply path 86 are equal is set, and the second target pressure P2 preferable for the temperature adjustment of the substrate S is obtained. When a volume of the gas supply path 86 is V1 and a volume of the gas path 84 is V2, by setting the first target pressure P1=P2×(V1+V2)/V1, the pressure in the equilibrium state is the second target pressure P2. A required time from the fifth timing t5 to the sixth timing t6 is 1 second or less, is, for example, 0.5 second or less, and is preferably 0.2 second or less.

The mass flow controller 96 may open the first valve 90 while the flow rate control valve 104 is closed and the supply of the gas from the gas supply source 94 to the gas supply path 86 is stopped, thereby setting the gas pressure in the gas supply path 86 to the second target pressure P2. The mass flow controller 96 may control the gas pressure in the gas supply path 86 such that the gas pressure becomes the second target pressure P2 by controlling the flow rate of the gas supplied to the gas supply path 86 with the flow rate control valve 104, based on at least one of the measurement values of the flow rate sensor 106 and the first pressure sensor 108.

When the gas pressure in the gas path 84 becomes the second target pressure P2 at the sixth timing t6, the gas pressure in the heat transfer space 82 also becomes the second target pressure P2, and the temperature of the substrate S held by the substrate holder 50 can be suitably adjusted. At the sixth timing t6, the processing on the substrate S is started. For example, the ion implantation processing of irradiating the substrate S with the ion beam is started. The start of the processing on the substrate S may be executed under a condition that a predetermined time has elapsed after the first valve 90 is opened at the fifth timing t5.

The processing on the substrate S may be started before the gas pressure in the gas path 84 reaches the second target pressure P2 at the sixth timing t6. For example, the processing on the substrate S may be started under a condition that the gas pressure in the gas path 84 exceeds the third target pressure P3. The third target pressure P3 can be set in a range of, for example, 1 torr or more and 5 torr or less. The control device 56 may start the processing on the substrate S under a condition that the measurement value of the third pressure sensor 112 exceeds the third target pressure P3 after the opening of the first valve 90. When the third pressure sensor 112 has the first differential pressure sensor, the control device 56 may start the processing on the substrate S under a condition that the first differential pressure signal indicating that the first threshold is exceeded is acquired from the first differential pressure sensor. The first threshold can be set in a range of, for example, 1 torr or more and 5 torr or less.

During the processing on the substrate from the sixth timing t6 to a seventh timing t7, the gas pressure in the gas supply path 86 is maintained at the second target pressure P2. Since the target pressure in the mass flow controller 96 is set to the second target pressure P2, the mass flow controller 96 controls the flow rate control valve 104 such that the gas pressure of the gas supply path 86 becomes the second target pressure P2. Accordingly, during the processing on the substrate, the gas pressure in the heat transfer space 82 is maintained at the second target pressure P2 through the gas path 84 and a state in which the temperature of the substrate S is suitably adjusted is maintained. In a case where the gas is not leaked from the heat transfer space 82, the gas path 84, and the gas supply path 86 during the processing on the substrate, the mass flow controller 96 may maintain the gas pressure in the gas supply path 86 at the second target pressure P2 by maintaining a state in which the flow rate control valve 104 is closed and the supply of the gas from the gas supply source 94 to the gas supply path 86 is stopped.

After a predetermined time elapses from the start of the processing on the substrate S at the sixth timing t6, the processing on the substrate S is completed at the seventh timing t7. For example, the irradiation of the substrate S with the ion beam is stopped. A processing time for the substrate S is set for each substrate or each lot as a processing condition for the substrate S.

Thereafter, the first valve 90 is closed at an eighth timing t8. For example, the control device 56 closes the first valve 90 under a condition that the processing on the substrate S is completed. The control device 56 may close the first valve 90 after a predetermined time elapses from the fifth timing t5 at which the first valve 90 is opened. The control device 56 may close the first valve 90 after a predetermined time elapses from the sixth timing t6 at which the gas pressure of the gas path 84 becomes the second target pressure P2 via the opening of the first valve 90.

Thereafter, the second valve 92 is opened at a ninth timing t9. The opening of the second valve 92 is executed under a condition that the substrate S is held by the substrate holder 50 and the processing on the substrate S is completed. It is preferable that the closing of the first valve 90 is also the condition for the opening of the second valve 92. However, in implementation on a device, a sequential relationship between the eighth timing t8 at which the first valve 90 is closed and the ninth timing t9 at which the second valve 92 is opened is not strictly required. That is, the ninth timing t9 at which the second valve 92 is opened may be simultaneous with the eighth timing t8 at which the first valve 90 is closed, or may be slightly earlier than the eighth timing t8 at which the first valve 90 is closed.

When the second valve 92 is opened at the ninth timing t9, the gas is exhausted from the gas path 84 to the gas exhaust path 88. The gas exhaust path 88 communicates with the internal space 16a of the vacuum processing chamber 16 via the gas exhaust port 98, and is maintained at the high vacuum pressure P0 by the vacuum exhaust system of the vacuum processing chamber 16. When the second valve 92 is opened, the gas pressure in the gas path 84 decreases from the second target pressure P2 toward the high vacuum pressure P0. In addition, when the second valve 92 is opened, the gas pressure in the gas exhaust path 88 increases and then decreases toward the high vacuum pressure P0.

Thereafter, when the pressures of the gas path 84 and the gas exhaust path 88 reach the third target pressure P3 at a tenth timing t10, the holding of the substrate S performed by the substrate holder 50 can be released. The third target pressure P3 is set to a pressure that is low enough not to cause bouncing of the substrate S due to a pressure difference between the front surface and the rear surface of the substrate S, and can be set in a range of, for example, 1 torr or higher and 5 torr or lower. The control device 56 turns off the voltage power supply applied to the chuck electrode 64 of the substrate holder 50 and releases the holding of the substrate S at an eleventh timing t11 under a condition that the measurement value of the second pressure sensor 110 or the third pressure sensor 112 is the third target pressure P3 or lower. When the third pressure sensor 112 has the first differential pressure sensor, the control device 56 may release the holding of the substrate S under a condition that the first differential pressure signal indicating that the first threshold is not exceeded is acquired from the first differential pressure sensor. The first threshold can be set in a range of, for example, 1 torr or higher and 5 torr or lower. After the holding of the substrate S is released at the eleventh timing t11, the processed substrate is unloaded from the vacuum processing chamber 16.

In the example shown in FIG. 4, the third target pressure P3 is set as a common threshold for the start of the processing on the substrate S and the release of the holding of the substrate S. In a modification example, the threshold for the start of the processing on the substrate S and the threshold for the release of the holding of the substrate S may be separately set. The threshold for the start of the processing on the substrate S may be higher than the threshold for the release of the holding of the substrate S. The threshold for the start of the processing on the substrate S may be lower than the threshold for the release of the holding of the substrate S.

The control device 56 may output an error and interrupt the processing on the substrate S in a case where the gas pressure in the gas path 84 exceeds the second threshold higher than the second target pressure P2 during a period from the third timing t3 at which the substrate S is held by the substrate holder 50 to the eleventh timing t11. The second threshold is set to a pressure that is high to an extent that the substrate S is difficult to be held due to a pressure difference between the front surface and the rear surface of the substrate S, and can be set in a range of, for example, 30 torr or higher and 100 torr or lower. The control device 56 may output an error in a case where the measurement value of the third pressure sensor 112 exceeds the second threshold. In a case where the third pressure sensor 112 has the second differential pressure sensor, the control device 56 may output an error under a condition that the second differential pressure signal indicating that the second threshold is exceeded is acquired from the second differential pressure sensor. When the gas pressure in the gas path 84 exceeds the second threshold, the control device 56 may open the second valve 92 to reduce the gas pressure in the gas path 84.

The processing flow shown in FIG. 4 can be repeatedly executed in order to continuously process a plurality of substrates S. For example, after a first substrate is unloaded at the eleventh timing t11, the processing flow in FIG. 4 can be executed from the first timing t1 for processing on a next second substrate. In this case, the first timing t1, at which the filling of the gas supply path 86 with the gas having the overfilling pressure (first target pressure P1) is started for the second substrate, may be before the eleventh timing t11 at which holding of the first substrate is released. For example, the filling of the gas supply path 86 with the gas having the overfilling pressure (first target pressure P1) can be started for the second substrate, as long as it is after the eighth timing t8 at which the processing on the first substrate is completed and the first valve 90 is closed. That is, processing of exhausting the gas from the heat transfer space 82 and releasing the holding of the first substrate in order to unload the first substrate and processing of overfilling the gas supply path 86 with the gas for the second substrate can be executed simultaneously as long as the first valve 90 is closed. As a result, an additional processing time for overfilling with the gas can be shortened or omitted, and the productivity of the substrate processing apparatus 10 can be improved.

In a case where the plurality of substrates S are continuously processed, the value of the second target pressure P2 may be changed in accordance with the processing condition or the like for each of the plurality of substrates S. For example, in a case of a processing condition under which the temperature of the substrate is likely to rise, the second target pressure P2 may be set to be higher than a standard value so that heat transfer efficiency between the substrate S and the substrate holder 50 is increased. In addition, in a case of high-temperature processing in which the temperature of the substrate is intentionally increased, the second target pressure P2 may be set to be lower than the standard value to intentionally reduce the heat transfer efficiency between the substrate S and the substrate holder 50 and promote the temperature increase of the substrate S. In a case where the second target pressure P2 is changed, the first target pressure P1 is also changed in accordance with the relational expression between the first target pressure P1 and the second target pressure P2.

The value of the second target pressure P2 may be changed in accordance with the temperature of the stage 60. For example, in a case where the processing is continuously performed for a long time, the cooling capacity of the stage 60 via the water flowing through the fluid flow path 62 may be insufficient, and the temperature of the stage 60 may increase. In a case where a measurement value of a temperature sensor that measures the temperature of the stage 60 increases and becomes higher than a predetermined threshold, the second target pressure P2 may be set to be higher than the standard value to increase the heat transfer efficiency between the substrate S and the substrate holder 50 and suppress a decrease in the cooling performance of the substrate S. In addition, the value of the second target pressure P2 may be changed in accordance with the number of times of processes of continuously processing the substrates. In a case where the second target pressure P2 is changed, the first target pressure P1 is also changed in accordance with the relational expression between the first target pressure P1 and the second target pressure P2.

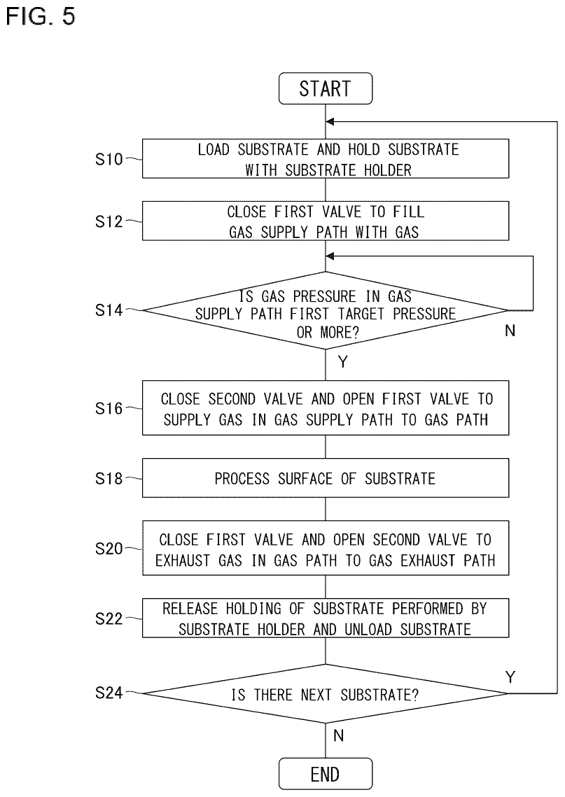

FIG. 5 is a flowchart showing an example of a substrate processing method according to the embodiment. The substrate S is loaded into the vacuum processing chamber 16 and is held by the substrate holder 50 (S10), and the first valve 90 is closed to fill the gas supply path 86 with the gas (S12). The filling with the gas is continued until the gas pressure in the gas supply path 86 becomes the first target pressure P1 or higher (N in S14), and in a case where the gas pressure in the gas supply path 86 becomes the first target pressure P1 or higher (Y in S14), the second valve 92 is closed, and the first valve 90 is opened to supply the gas in the gas supply path 86 to the gas path 84 (S16). Subsequently, the surface of the substrate S is processed (S18), the first valve 90 is closed after the processing on the substrate S, and the second valve 92 is opened to exhaust the gas in the gas path 84 to the gas exhaust path 88 (S20). After opening of the second valve 92, the holding of the substrate S performed by the substrate holder 50 is released and the substrate S is unloaded from the vacuum processing chamber 16 (S22). When there is a substrate S to be processed next (Y in S24), the processes in S10 to S22 are repeated. If there is no substrate S to be processed next (N in S24), the present flow is ended.

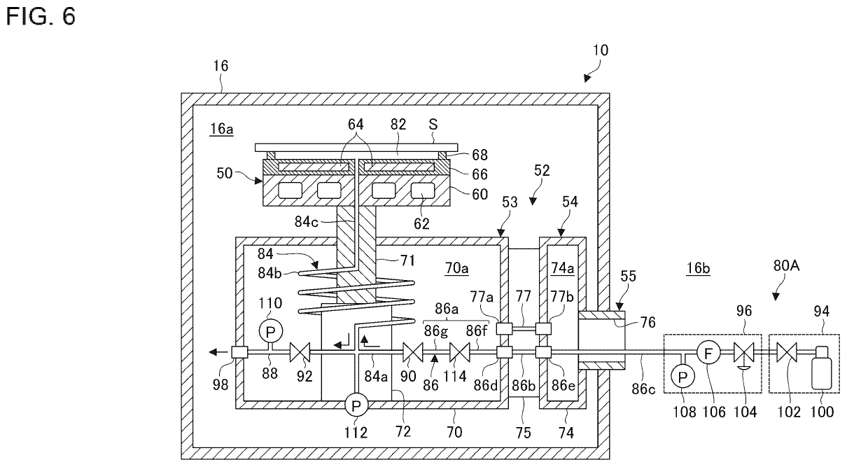

FIG. 6 is a diagram showing a configuration of a heat transfer gas supply/exhaust system 80A according to a first modification example. In the first modification example, the third valve 114 that is capable of opening and closing the first gas supply path 86a is further provided, which is different from the above-described embodiment. The first modification example will be described with a focus on differences from the above-described embodiment, and common points will be appropriately omitted.

The heat transfer gas supply/exhaust system 80A includes the heat transfer space 82, the gas path 84, the gas supply path 86, the gas exhaust path 88, the first valve 90, the second valve 92, the gas supply source 94, the mass flow controller 96, the gas exhaust port 98, and the third valve 114.

The third valve 114 is provided in the internal space 70a of the first hermetic container 70. The third valve 114 is provided in the middle of the first gas supply path 86a, and is capable of opening and closing the first gas supply path 86a. The third valve 114 is, for example, a solenoid valve, and is configured to be openable and closable in accordance with a command from the control device 56. The first gas supply path 86a is divided into a first portion 86f provided between the first connecting part 86d and the third valve 114, and into a second portion 86g provided between the third valve 114 and the first valve 90.

The third valve 114 is opened when the first valve 90 is closed. The third valve 114 is opened after closing the first valve 90 and opening the second valve 92 in order to exhaust the gas in the gas path 84. The third valve 114 is opened with closing the first valve 90 in a process of overfilling the gas supply path 86 with the gas to set the gas pressure therein to the first target pressure P1. Therefore, in the process of overfilling the gas supply path 86 with the gas, the second portion 86g between the third valve 114 and the first valve 90 is filled with the gas having the first target pressure P1.

The third valve 114 is closed before the first valve 90 is opened. The third valve 114 is closed after the gas pressure in the gas supply path 86 becomes the first target pressure P1. The third valve 114 is closed before the supply of the gas from the gas supply path 86 to the gas path 84 is started by opening the first valve 90. When the first valve 90 is opened, the gas used for filling the second portion 86g between the first valve 90 and the third valve 114 is supplied to the gas path 84.

According to the present modification example, the gas can be supplied from the second portion 86g having a volume V3 smaller than the volume V1 of the entire gas supply path 86 to the gas path 84 by providing the third valve 114. A time required for the gas pressure in the gas path 84 to reach the second target pressure P2 can be shortened by setting the volume V3 of the second portion 86g to be smaller than the volume V1. In the present modification example, the first target pressure P1=P2×(V3+V2)/V3.

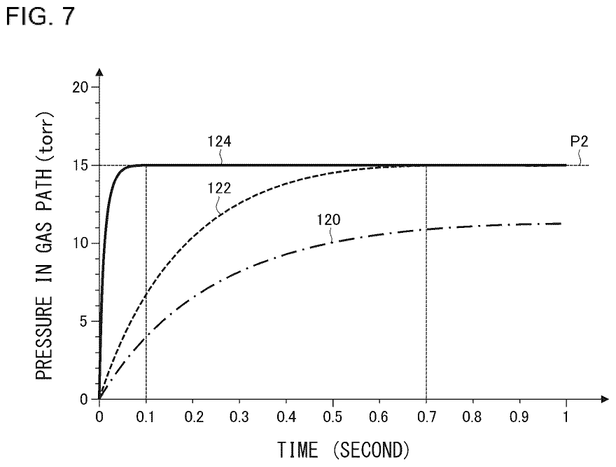

FIG. 7 is a graph showing an example of a pressure change in the gas path 84 when the first valve 90 is opened. A curved line 120 is a comparative example in which the gas supply path 86 is not overfilled with the gas. A curved line 122 is an example in which the gas supply path 86 is overfilled with the gas without providing the third valve 114, and corresponds to the embodiment of FIG. 3 described above. A curved line 124 is an example in which the third valve 114 is provided and the gas supply path 86 is overfilled with the gas, and corresponds to a modification example in FIG. 6. In FIG. 7, the second target pressure P2 is set to 15 torr, the volume V1 of the gas supply path 86 is set to 150 cm³, the volume V2 of the gas path 84 is set to 50 cm³, and the volume V3 of the second portion 86g is set to 10 cm³.

Under a condition of the curved line 120 as a comparative example, the gas supply path 86 is not overfilled with the gas, and the target pressure of the mass flow controller 96 is changed from 0 torr to the second target pressure P2 at the same time as the first valve 90 is opened. In this manner, the gas is supplied from the gas supply path 86 to the gas path 84. In this case, the pressure in the gas path 84 one second after the opening of the first valve 90 is approximately 11 torr, and does not reach the second target pressure P2. Under this condition, it takes 5 seconds or more to reach the second target pressure P2. Under a condition of the curved line 122 as the example, the first target pressure P1 is set to 20 torr, and the gas supply path 86 is overfilled with the gas, so that the pressure in the gas path 84 can reach the second target pressure P2 0.7 seconds after the opening of the first valve 90. Under a condition of the curved line 124 as the example, the first target pressure P1 is set to 100 torr, and the gas supply path 86 is overfilled with the gas, so that the pressure in the gas path 84 can reach the second target pressure P2 0.1 seconds after the opening of the first valve 90. As described above, the volume V3 of the second portion 86g overfilled with the gas supplied to the gas path 84 is set to be small, and the first target pressure P1 of the gas used for overfilling the second portion 86g is increased, so that the time required for the gas pressure in the gas path 84 to reach the second target pressure P2 can be shortened.

In order to shorten the time required for the pressure of the gas path 84 to reach the second target pressure P2, it is effective that the volume V3 of the second portion 86g is set to be smaller than the volume V2 of the gas path 84, and for example, it is preferable that the volume V3 of the second portion 86g is set to be 50% or less or 20% or less of the volume V2 of the gas path 84. In addition, when the volume V3 of the second portion 86g is too small, the first target pressure P1 needs to be extremely high. Therefore, it is preferable that the volume V3 of the second portion 86g is 5% or more of the volume V2 of the gas path 84.

In a case where the volume V3 of the second portion 86g is set to be smaller than the volume V2 of the gas path 84, the first target pressure P1 needs to be set to two times the second target pressure P2 or higher. In a case where the volume V3 of the second portion 86g is set to 5% of the volume V2 of the gas path 84, the first target pressure P1 needs to be set to 21 times the second target pressure P2. For example, when the second target pressure P2 is 1 torr or more and 100 torr or less, the first target pressure P1 can be set in a range of 2 torr or more and 2100 torr or less.

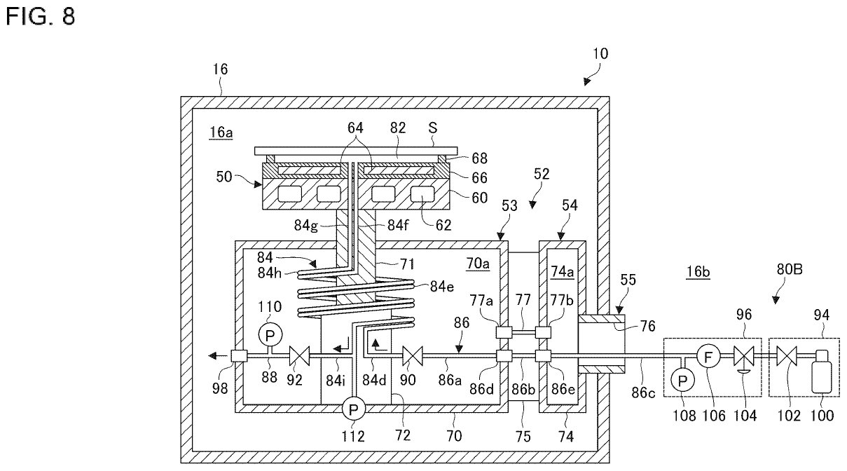

FIG. 8 is a diagram showing a configuration of a heat transfer gas supply/exhaust system 80B according to a second modification example. In the second modification example, a forward path and a return path of the gas path 84 are separated from each other, and the gas path 84 is formed of the forward path connecting the first valve 90 and the heat transfer space 82 and the return path connecting the heat transfer space 82 and the second valve 92. The second modification example will be described with a focus on differences from the above-described embodiment, and common points will be appropriately omitted.

The gas path 84 has a first gas path 84d, a second gas path 84e, a third gas path 84f, a fourth gas path 84g, a fifth gas path 84h, and a sixth gas path 84i. The first gas path 84d is provided in the internal space 70a of the first hermetic container 70 and is connected to the first valve 90. The second gas path 84e is provided in the internal space 70a of the first hermetic container 70 and extends spirally around the support shaft 71. The third gas path 84f extends inside the substrate holder 50 and the support shaft 71. The first gas path 84d, the second gas path 84e, and the third gas path 84f form the forward path for supplying the gas from the first valve 90 to the heat transfer space 82.

The fourth gas path 84g extends inside the substrate holder 50 and the support shaft 71. The fifth gas path 84h is provided in the internal space 70a of the first hermetic container 70 and extends spirally around the support shaft 71. The sixth gas path 84i is provided in the internal space 70a of the first hermetic container 70 and is connected to the second valve 92. The fourth gas path 84g, the fifth gas path 84h, and the sixth gas path 84i form the return path for exhausting the gas from the heat transfer space 82 toward the second valve 92.

The third pressure sensor 112 may be provided in the first gas path 84d or the sixth gas path 84i.

In the present modification example, the second gas path 84e is spirally formed, thereby reconciling both the rotation of the third gas path 84f with respect to the first gas path 84d and the connection between the first gas path 84d and the third gas path 84f. In addition, the fifth gas path 84h is spirally formed, thereby reconciling both the rotation of the fourth gas path 84g with respect to the sixth gas path 84i and the connection between the sixth gas path 84i and the fourth gas path 84g. The second gas path 84e and the fifth gas path 84h may have a mechanical sealing mechanism without rotation restriction instead of being spirally formed.

Also in the present modification example, the same effects as those of the above-described embodiment can be obtained.

Although the present disclosure has been described above with reference to each of the above-described embodiments, the present disclosure is not limited to each of the above-described embodiments, and the configuration of each of the above-described embodiments may be combined or may be replaced as appropriate. In addition, the combination or the processing order in each embodiment can be appropriately rearranged, based on the knowledge of those skilled in the art, and modifications such as various design changes can be added to the embodiments. The embodiments to which the rearrangement or the modifications are added in this way may also be included in the scope of the substrate processing apparatus, the substrate processing method, and the method for manufacturing a semiconductor device according to the present disclosure.

It is apparent to those skilled in the art that the above-described heat transfer gas supply/exhaust systems 80, 80A, and 80B can be applied to any substrate processing apparatus for processing a substrate S inside a vacuum processing chamber, and are not limited to the above-described ion implanter. The substrate processing apparatus according to the present disclosure may be a thin film deposition apparatus using a thin film deposition method such as chemical vapor deposition (CVD), physical vapor deposition (PVD), or molecular beam epitaxy (MBE), or may be a plasma treatment apparatus, an etching apparatus, or an ashing apparatus. In a case where the substrate S is a semiconductor wafer, the method for manufacturing a semiconductor device can include the above-described substrate processing method. The method for manufacturing a semiconductor device according to the present disclosure may include a thin film deposition process, a plasma treatment process, an etching process, an ashing process, or the like instead of or in addition to the above-described ion implantation process.

The embodiments according to the present disclosure may adopt a form of a computer program including one or more computer-readable sequences for describing the methods according to the present disclosure, or may adopt a form of a non-temporary and tangible storage medium (for example, a non-volatile memory, a magnetic tape, a magnetic disk, or an optical disk) storing the computer program. The processor may achieve the methods according to the present disclosure by executing the computer program.

According to the non-limiting exemplary embodiment of the present invention, it is possible to provide a technique for improving productivity in a semiconductor manufacturing process.

It should be understood that the invention is not limited to the above-described embodiment, but may be modified into various forms on the basis of the spirit of the invention. Additionally, the modifications are included in the scope of the invention.

What is claimed is:

1. A substrate processing apparatus comprising:
a vacuum processing chamber in which processing on a substrate is performed;
a substrate holder provided in the vacuum processing chamber and configured to hold the substrate;
a sealing configured to form a closed space between the substrate held by the substrate holder and the substrate holder;
a hermetic container provided in the vacuum processing chamber and having a gas pressure higher than a gas pressure in the vacuum processing chamber;
a gas path provided in the hermetic container and communicating with the closed space;
a gas supply path configured to supply a gas into the gas path;
a gas exhaust path configured to exhaust the gas from the gas path;
a first valve provided in the hermetic container and capable of opening and closing a space between the gas path and the gas supply path; and
a second valve provided in the hermetic container and capable of opening and closing a space between the gas path and the gas exhaust path.

2. The substrate processing apparatus according to claim 1, further comprising:
a flow rate sensor configured to measure a flow rate of the gas supplied to the gas supply path; and
a flow rate control valve configured to control the flow rate of the gas supplied to the gas supply path based on a measurement value of the flow rate sensor.

3. The substrate processing apparatus according to claim 2, further comprising:
a first pressure sensor configured to measure a gas pressure in the gas supply path,
wherein the flow rate control valve controls the flow rate of the gas supplied to the gas supply path further based on a measurement value of the first pressure sensor.

4. The substrate processing apparatus according to claim 1, further comprising:
a second pressure sensor configured to measure a gas pressure in the gas exhaust path.

5. The substrate processing apparatus according to claim 1, further comprising:
a third pressure sensor configured to measure a gas pressure in the gas path.

6. The substrate processing apparatus according to claim 1, further comprising:
a first differential pressure sensor configured to output a first differential pressure signal indicating whether or not a difference between a gas pressure in the gas path and the gas pressure in the vacuum processing chamber exceeds a first threshold.

7. The substrate processing apparatus according to claim 6, further comprising:
a second differential pressure sensor configured to output a second differential pressure signal indicating whether or not the difference between the gas pressure in the gas path and the gas pressure in the vacuum processing chamber exceeds a second threshold higher than the first threshold.

8. The substrate processing apparatus according to claim 1, further comprising:
a third valve provided in the hermetic container and capable of opening and closing the gas supply path,
wherein the first valve is provided between the third valve and the gas path.

9. The substrate processing apparatus according to claim 8,
wherein a volume of the gas supply path between the first valve and the third valve is smaller than a volume of the gas path.

10. The substrate processing apparatus according to claim 9,
wherein the volume of the gas supply path between the first valve and the third valve is 5% or more and 20% or less of the volume of the gas path.

11. The substrate processing apparatus according to claim 1, further comprising:
a support mechanism provided in the vacuum processing chamber and configured to support the substrate holder,
wherein the hermetic container is provided in the support mechanism.

12. The substrate processing apparatus according to claim 11,
wherein the support mechanism includes a twist mechanism configured to rotate the substrate holder.

13. A substrate processing method of processing a substrate held by a substrate holder in a vacuum processing chamber,
wherein a gas path communicating with a closed space formed between the substrate held by the substrate holder and the substrate holder is connected to a gas supply path via a first valve that is openable and closable, and the gas path is further connected to a gas exhaust path via a second valve that is openable and closable, and
the substrate processing method comprises:
holding the substrate on the substrate holder;
closing the first valve to set a gas pressure in the gas supply path to a first target pressure;
opening the first valve to supply a gas in the gas supply path to the gas path after the substrate is held by the substrate holder and the gas pressure in the gas supply path becomes the first target pressure;
processing a surface of the substrate after the opening of the first valve;
closing the first valve and opening the second valve to exhaust the gas in the gas path to the gas exhaust path; and
releasing the holding of the substrate performed by the substrate holder after the opening of the second valve.

14. The substrate processing method according to claim 13,
wherein setting the gas pressure in the gas supply path to the first target pressure includes
acquiring a measurement value of a flow rate sensor configured to measure a flow rate of the gas supplied to the gas supply path, and
controlling the flow rate of the gas supplied to the gas supply path and a supply time of the gas with a flow rate control valve based on the measurement value of the flow rate sensor.

15. The substrate processing method according to claim 13,
wherein setting the gas pressure in the gas supply path to the first target pressure includes
acquiring a measurement value of a first pressure sensor configured to measure the gas pressure in the gas supply path, and
controlling a flow rate of the gas supplied to the gas supply path with a flow rate control valve based on the measurement value of the first pressure sensor.

16. The substrate processing method according to claim 13,
wherein the processing on the surface of the substrate is started after a predetermined time elapses from the opening of the first valve.

17. The substrate processing method according to claim 13, further comprising:
acquiring a differential pressure signal indicating whether or not a difference between a gas pressure in the gas path and a gas pressure in the vacuum processing chamber exceeds a threshold, from a differential pressure sensor,
wherein the processing on the surface of the substrate is started in a case where the differential pressure signal acquired from the differential pressure sensor indicates that the threshold is exceeded after the opening of the first valve.

18. The substrate processing method according to claim 13,
wherein the first valve is closed after a predetermined time elapses from the opening of the first valve.

19. The substrate processing method according to claim 13,
wherein the holding of the substrate performed by the substrate holder is released after a predetermined time elapses from the opening of the second valve.

20. The substrate processing method according to claim 13, further comprising:
acquiring a differential pressure signal indicating whether or not a difference between a gas pressure in the gas path and a gas pressure in the vacuum processing chamber exceeds a threshold, from a differential pressure sensor,
wherein the holding of the substrate performed by the substrate holder is released in a case where the differential pressure signal acquired from the differential pressure sensor indicates that the threshold is not exceeded after the opening of the second valve.

21. The substrate processing method according to claim 13,
wherein the first target pressure is 2 torr or higher and 2100 torr or lower.

22. The substrate processing method according to claim 13,
wherein opening the first valve to supply the gas in the gas supply path to the gas path includes setting a gas pressure in the gas path to a second target pressure lower than the first target pressure.

23. The substrate processing method according to claim 22,
wherein a relational expression that P1=P2×(V1+V2)/V1 is satisfied for the first target pressure P1, using a volume V1 of the gas supply path, a volume V2 of the gas path, and the second target pressure P2.

24. The substrate processing method according to claim 22,
wherein setting the gas pressure in the gas path to the second target pressure includes
acquiring a measurement value of a flow rate sensor configured to measure a flow rate of the gas supplied to the gas supply path,
acquiring a measurement value of a first pressure sensor configured to measure the gas pressure in the gas supply path, and
controlling the flow rate of the gas supplied to the gas supply path with a flow rate control valve based on the measurement value of the flow rate sensor and the measurement value of the first pressure sensor.

25. The substrate processing method according to claim 22,
wherein setting the gas pressure in the gas path to the second target pressure includes opening the first valve while the supply of the gas to the gas supply path is stopped.

26. The substrate processing method according to claim 22,
wherein the first valve is closed after a predetermined time elapses after the gas pressure in the gas path becomes the second target pressure via the opening of the first valve.

27. The substrate processing method according to claim 22,
wherein the holding of the substrate performed by the substrate holder is released after the gas pressure in the gas path becomes a third target pressure lower than the second target pressure via the opening of the second valve.

28. The substrate processing method according to claim 22,
wherein the second target pressure is 1 torr or higher and 100 torr or lower.

29. The substrate processing method according to claim 22,
wherein the second target pressure is 3 torr or higher and 30 torr or lower.

30. The substrate processing method according to claim 22,
wherein the second target pressure is 5 torr or higher and 15 torr or lower.

31. The substrate processing method according to claim 13
wherein processing the surface of the substrate includes implanting ions into the substrate.

32. A method for manufacturing a semiconductor device, comprising:
the substrate processing method according to claim 13.
